(19) United States
(12) Patent Application Publication
(10) Pub. No.: US 2012/0147549 A1
(43) Pub. Date: Jun. 14, 2012

(54) RACK SERVER

(75) Inventors: HUNG-YI WU, Tu-Cheng (TW); XIAO-ZHU CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/980,306

(22) Filed: Dec. 28, 2010

(30) Foreign Application Priority Data
Dec. 8, 2010 (CN) 201010579118.6

(51) Int. Cl. H05K 7/00; H05K 7/20

(52) U.S. Cl. 361/679.33; 361/679.48

(57) ABSTRACT

An exemplary rack server includes a chassis, a fan unit arranged at a central portion of the chassis, and two processing units respectively arranged at opposites sides of the fan unit. Each of the processing units includes a main board, a hard disk drive and a power source for supplying electric currents to the main board and the hard disk drive.

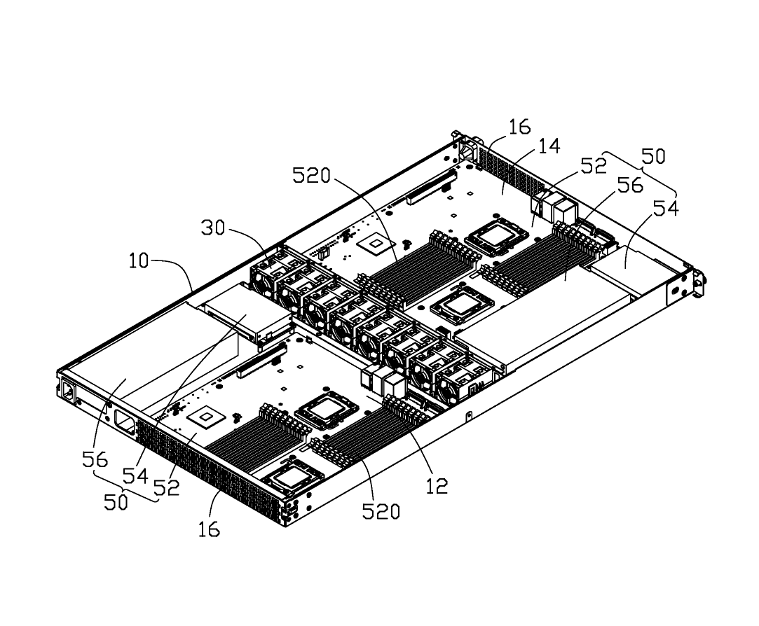

### BACKGROUND

1. Technical Field

The disclosure relates to servers, and particularly to rack servers.

2. Description of Related Art

Nowadays, rack servers are widely used in the construction of large information systems. Rack servers provide flexible arrangement and allow high computing capability. A rack server generally includes a chassis and a processing system mounted in the chassis. The processing system includes a main board, a hard disk, and a power source for supplying electric current to the main board and the hard disk. Designing a new main board is a common method for improving the capability of a rack server. However, the time period needed for testing the newly designed main board is long, and the new rack server may not be able to satisfy the needs of the marketplace in time.

What is needed, therefore, is a means which can overcome the limitations described.

### BRIEF DESCRIPTION OF THE DRAWING

The drawing is an isometric view of a rack server in accordance with an embodiment of the disclosure.

### DETAILED DESCRIPTION

Referring to the drawing, a rack server in accordance with an exemplary embodiment is shown. In this embodiment, the rack server is a standard 1U (one rack unit) rack server which has a height of 1.75 inches, i.e., about 4.445 cm (centimeters).

The rack server includes a chassis 10, a fan unit 30, and two processing units 50. The fan unit 30 and the processing units 50 are disposed in the chassis 10. The fan unit 30 is disposed at a central portion of the chassis 10, and the two processing units 50 are disposed at opposite sides of the fan unit 30, respectively.

In this embodiment, the fan unit 30 includes a plurality of axial fans arranged side by side along a width direction of the chassis 10. The fan unit 30 separates an interior of the chassis 10 into a front space 12 at a front side of the fan unit 30, and a rear space 14 at a rear side of the fan unit 30. Air inlets of the axial fans of the fan unit 30 face the front space 12 of the interior of the chassis 10, and air outlets of the axial fans of the fan unit 30 face the rear space 14 of the interior of the chassis 10. A plurality of ventilating holes 16 are respectively defined in front and rear sides of the chassis 10, to communicate the interior of the chassis 10 with the outside.

The two processing units 50 are respectively received in the front space 12 and the rear space 14 of the interior of the chassis 10. Each of the processing unit 50 includes a main board 52, a hard disk drive (HDD) 54 and a power source 56. The power source 56 is adapted for supplying electric currents to drive the main board 52 and the HDD 54. The HDD 54 is adapted for storing data. A number and a type of the HDD 54 can be varied according to need.

In this embodiment, the main boards 52 of the two processing units 50 are respectively located at two diagonal corners of the chassis 10. The main boards 52 are conventional main boards which can be easily obtained in the marketplace. A plurality of electronic components, such as a CPU (central processing unit), chips, etc, is arranged on each of the main boards 52. A plurality of sockets 520 is mounted on each of the main boards 52, for connecting memory cards, etc.

During operation of the rack server, both of the two processing units 50 operate, thereby enhancing a processing capability of the rack server. During operation of the processing units 50, heat is generated. The fan unit 30 operates to draw in cooling air via the ventilating holes 16 of the front side of the chassis 10. The cooling air flows through the chassis 10 and exchanges heat with the components, including the HDDs 54 and the electronic components on the main boards 52. The air finally exhausts from the chassis 10 through the ventilating holes 16, thereby dissipating the heat generated by the components of the rack server to the outside, and helping to maintain stable operation of the rack server. Since the main boards 52 can be conventional main boards, the rack server adopting such main boards 52 does not need a long time for testing before being released into the marketplace. That is, any newly designed such rack server can be quickly introduced into the marketplace.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A rack server, comprising:
a chassis;
a fan unit arranged at a central portion of the chassis; and
two processing units arranged at opposites sides of the fan unit, respectively, each of the processing units comprising a main board, a hard disk drive and a power source for supplying electric currents to the main board and the hard disk drive.

2. The rack server of claim 1, wherein the rack server is a standard 1U rack server.

3. The rack server of claim 1, wherein each of the main board has a socket mounted thereon for connecting electronic component.

4. The rack server of claim 1, wherein each of the main boards has a central processing unit mounted thereon.

5. The rack server of claim 1, wherein the main boards of the two processing units are respectively located at two diagonal corners of the chassis.

6. The rack server of claim 1, wherein the fan unit comprises a plurality of axial fans arranged with air inlets thereof facing one of the two processing units and air outlets thereof acing the other one of the two processing units.

7. The rack server of claim 6, wherein the axial fans of the fan unit are arranged along a width direction of the chassis, and separates an interior of the chassis into a front space before the fan unit and a rear space behind the fan unit, the two processing units being respectively received in the front space and the rear space.

8. The rack server of claim 7, wherein a plurality of ventilating holes is defined in front and rear sides of the chassis for communicating the interior of the chassis with the outside.

9. A rack server, comprising:
two processing units, each of the processing units comprising a main board, a hard disk drive and a power source for supplying electric currents to the main board; and
a chassis defining two separate spaces respectively receiving the two processing units.

10. The rack server of claim 9, further comprising a fan unit disposed between the two processing units.

11. The rack server of claim 10, wherein the fan unit comprises a plurality of axial fans arranged with air inlets thereof facing one of the two processing units and air outlets thereof acing the other one of the two processing units

12. The rack server of claim 9, wherein a plurality of ventilating holes are defined in the chassis communicating the spaces with the outside.

13. A rack server, comprising:
a chassis defining two separate spaces therein and defining a plurality of ventilating holes is defined in two opposite sides thereof communicating the two separate spaces with the outside;
two processing units respectively received in the two separates spaces of the chassis, each of the processing units comprising a main board, a hard disk drive and a power source for supplying electric currents to the main board and the hard disk drive; and
a fan unit received in the chassis and located between the two separate spaces, the fan unit comprising a plurality of axial fans arranged with air inlets thereof facing one of the two processing units and air outlets thereof acing the other one of the two processing units.
